(19) United States
(12) Patent Application Publication
(10) Pub. No.: US 2007/0023916 A1
(43) Pub. Date: Feb. 1, 2007

(54) Semiconductor structure with multiple bottom anti-reflective coating layer and method of forming photoresist pattern and pattern of semiconductor device using the same structure

(76) Inventors: Jung-hwan Hah, Hwaseong-si (KR); Yun-sook Chae, Suwon-si (KR); Han-ku Cho, Seongnam-si (KR); Chang-jin Kang, Seongnam-si (KR); Sang-gyun Woo, Yongin-si (KR); Man-hyoung Ryoo, Hwaseong-si (KR); Young-jae Jung, Daejeon Metropolitan City (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/494,469

(22) Filed: Jul. 28, 2006

(30) Foreign Application Priority Data
Jul. 30, 2005 (KR) 10-2005-0070028

(51) Int. Cl. H01L 23/52

(52) U.S. Cl. 257/758

(57) ABSTRACT

The semiconductor structure includes an etch target layer to be pattemed, a multiple bottom anti-reflective coating (BARC) layer, and a photoresist (PR) pattern. The multiple BARC layer includes a first mask layer formed on the etch target layer and containing carbon, and a second mask layer formed on the first mask layer and containing silicon. A PR layer formed on the multiple BARC layer undergoes photolithography to form the PR pattern on the multiple BARC layer. The multiple BARC layer has a reflectance of 2% or less, and an interface angle between the PR pattern and the multiple BARC layer is 80° to 90°.

### BACKGROUND OF THE INVENTION

1. Field of the Invention

The present invention generally relates to semiconductor device and fabrication methods thereof, and more particularly, the present invention relates to a hard mask of a multiple bottom anti-reflective coating (BARC) layer for forming a fine pattern of a semiconductor device and a method of fabricating a semiconductor device by using the multiple BARC layer.

A claim of priority is made to Korean Patent Application No. 10-2005-0070028, filed on Jul. 30, 2005, in the Korean Intellectual Property Office, the disclosure of which is incorporated herein in its entirety by reference.

2. Description of the Related Art

In semiconductor device fabricating processes, a patterning process is performed to pattern a material layer on a wafer. Generally, the patterning process sequentially includes photoresist (PR) coating, exposure, and development. The patterning process resolution is the most important factor for obtaining a fine pattern, and is primarily dependent upon light source and lens characteristics used in a photo process.

The high integration of the semiconductor device and the consequential decrease of the corresponding design rule lead to the need for a continuous increase in a resolution of a photolithography process. Accordingly, the realization of a high resolution has been required to overcome the limits of a light source and a lens used in a conventional optical lithography process, and thus many researches have been conducted to develop a numerical aperture (NA) of a lens and a resolution enhancement technique (RET).

Due to these efforts, the resolution has been enhanced to be able to fabricate 60-nm grade device by dry argon fluoride (ArF) lithography. However, with this resolution enhancement, the photolithography process has some limits. That is, a process margin and a device yield decrease with an increase in serious defects, such as a short (μ-bridge) between fine patterns and pattern collapse, and a PR layer for patterning cannot fully function as a mask for a subsequent etching process due to a continuous decrease in the thickness (Tpr) of the PR layer. Also, the use of a high NA causes an increase in a light incidence angle, leading to an increase in a light reflectance.

In an effort to overcome the problems associated with a decrease in Tpr and an increase in light reflectance, a multiple BARC (bottom anti-reflective coating) structure has been proposed that functions as an anti-reflection layer and a mask (also called a “hard mask” in contrast to a PR mask) between a PR layer and an etch target layer.

FIG. 1A is a sectional view of a conventional four-layer multiple BARC structure.

Referring to FIG. 1A, a multiple BARC layer 20 is stacked on an etch target layer 10, and a PR layer 30 is formed on the multiple BARC layer 20. The multiple BARC layer 20 includes a carbon layer 22 formed on the etch target layer 10, a silicon oxynitride (SiON) layer 24 formed on the carbon layer 22, and a thin BARC layer 26 formed on the SiON layer 24. Consequently, the four-layer multiple BARC structure is constructed to include the four layers sequentially stacked on the etch target layer 10, that is, the three-layer multiple BARC layer 20 (i.e., the carbon layer 22, the SiON layer 24, the thin BARC layer 26 ) and the PR layer 30.

FIG. 1B is a sectional view of a conventional three-layer multiple BARC structure.

Referring to FIG. 1B, a multiple BARC layer 20a is stacked on an etch target layer 10, and a PR layer (or pattern) 30 is formed on the multiple BARC layer 20a. The multiple BARC layer 20a includes a carbon layer 22 formed on the etch target layer 10, and a spin on glass (SOG) silicon layer 28 formed on the carbon layer 22. Consequently, the three-layer multiple BARC structure is constructed to include the three layers sequentially stacked on the etch target layer 10, that is, the two-layer multiple BARC layer 20 a (i.e., the carbon layer 22 and the SOG silicon layer 28) and the PR layer 30.

The four-layer and three-layer multiple BARC structures are most widely used in a current ArF process. The main difference between the two multiple BARC structures is that the opaque SiON layer 24 is used in the four-layer multiple BARC structure while the transparent SOG silicon layer 28 is used in the three-layer multiple BARC structure. In the four-layer and three-layer multiple BARC structures, a thin silicon layer (which corresponds to the SiON layer 24 or the SOG silicon layer 28 and will be hereinafter referred to as a “second mask layer”) is first patterned by a PR process. Thereafter, the carbon layer 22 (hereinafter referred to as a “first mask layer”) is patterned using the patterned second mask layer as a mask. Finally, using the patterned first mask layer as a mask, a pattern is transferred onto the etch target layer 10 formed of, for example, a silicon oxide (SiO₂), a silicon nitride (SiN), or a metal-based material. The two multiple BARC structures are similar in that, since the etch target layer 10 cannot be directly etched using a thin PR layer as a mask, it is patterned by a multiple mask process of sequentially etching the second mask layer 24 or 28 and the first mask layer 22. However, the two multiple BARC structures exhibit a significant difference in optical characteristics, which will now be described with reference to FIGS. 2 through 4.

FIG. 2 is a graph illustrating the amount incident light energy that is absorbed at each layer of the four-layer multiple BARC structure illustrated in FIG. 1A.

As can be seen from FIG. 2, about 30% of the incident light energy is absorbed at the PR layer 10 and about 68% of the incident light energy is absorbed at the SiON layer 24 and the thin BARC layer 26. Particularly, the incident light energy is significantly absorbed at the thin BARC layer 26 formed of polyacrylate or polyester. Consequently, it can be seen that the first mask layer 22 below the SION layer 24 has little energy absorption capability, that is, little anti-reflection capability.

Although not illustrated in the graph, the second mask layer 28 of the three-layer multiple BARC structure, that is, the transparent SOG silicon layer 28, has little anti-reflection capability due to its energy absorptance of nearly 0%. Accordingly, most of the incident light is incident onto and absorbed at the first mask layer 22.

As described above, while having the similar etching processes, the fourth-layer and three-layer BARC structures have the different optical characteristics. These different optical characteristics result in a profile difference between PR patterns that are formed using the four-layer multiple BARC structure and the three-layer multiple BARC structure, respectively, as is explained below in connection with FIGS. 3A and 3B.

FIGS. 3A and 3B are profile pictures of PR patterns having different second mask layer thickness in the four-layer and three-layer multiple BARC structures, respectively. In particular, FIG. 3A illustrates SION thicknesses of 260 Å, 400 Å and 600 Å in a four-layer BARC structure, and FIG. 3B illustrates SOG thicknesses of 1000 Å, 1100 Å and 1200 Å in a three-layer BARC structure.

As can be seen from FIG. 3A, the PR pattern formed using the four-layer multiple BARC structure has an undercut profile structure that is constant irrespective of the thickness of the second mask layer (the SiON layer 24), but is generally weak against pattern collapse. On the contrary, as can be seen from FIG. 3B, while a profile structure is changed according to the thickness of the second mask layer (the SOG silicon layer 28), the PR pattern formed using the three-layer multiple BARC structure can have a slight footing profile that is robust against a pattern collapse at a proper thickness. This difference results from a reflectance difference between BARC/PR interfaces, as can bee seen from FIGS. 4A and 4B.

FIGS. 4A and 4B are graphs illustrating the reflectances of the BARC/PR interfaces depending on the thicknesses of the second mask layers, and the profile pictures of the PR patterns at positions corresponding to the thicknesses illustrated in FIGS. 3A and 3B.

As can be seen from FIG. 4A, the reflectance at the BARC/PR interface (Resist Bot.) has a relatively stable value of about 1%. However, due to the thin BARC layer 26 formed on the SiON layer 24, an incident light reflected by the thin BARC layer 26 and an incident light reflected by the second mask layer (the SiON layer) 24 are constructively interfered with each other at the BARC/PR interface. Accordingly, the BARC/PR interface is over-etched and thus the PR pattern has an undercut profile structure that is weak against a pattern collapse, leading to a decrease in process margin and device yield. A picture at the right-hand side of the PR pattern profile picture illustrates a concentration of a photo-acid generator (PAG) according to the thickness of the PR pattern. As can be seen from the concentration picture, the concentration has different values depending on depth. In particular, the PAG concentration has a high value at the BARC/PR interface. For this reason, the undercut profile structure is formed in the photolithography process.

As can be seen from FIG. 4B, since the second mask layer of the three-layer multiple BARC structure is the transparent SOG silicon layer 28, the reflectance at the BARC/PR interface (Here, the BARC becomes an SOG layer) has a relatively high value of above 4%. Also, since the path difference of the incident light is changed according to the thickness of the second mask layer, a change of the interference is generated at the BARC/PR interface and thus the reflectance is rapidly changed. Accordingly, the slight footing structure that is robust against a pattern collapse is formed at the proper thickness of the second mask layer, but the undercut structure that is weak against a pattern collapse or a heavy footing structure is formed at the improper thickness of the second mask layer. For reference, the heavy footing structure is formed if an interface angle between the PR pattern and the BARC layer (a BARC/PR interface angle) is less than or equal to 80°, and the undercut structure is formed if the BARC/PR interface angle is greater than or equal to 90°. Accordingly, the slight footing structure is formed if the BARC/PR interface angle is between 80° and 90°. Preferably, the slight footing structure is most robust against a pattern collapse if the BARC/PR interface angle is 85°.

The advantages and disadvantages of the four-layer and three layer multiple BARC structures are summarized in Table 1 below.

TABLE 1

| Stack | Four-layer | Three-layer |
|---|---|---|
| Feature | SiON (deposition): | SOG (spin-on): |
| | n = 2.219, k = −0.703 | n = 1.5, k = 0 |
| Advantage | Robust against thickness | Robust against collapse, |
| | change, minimum | Spin-on Si mask |
| | reflectance < 1% | |
| Disadvantage | Weak against collapse, | Sensitive to thickness |
| | complex, CVD | change, high reflectance |

Referring to Table 1, in the four-layer multiple BARC structure, layers are stacked by deposition, and the opaque SiON layer is used as the second mask layer. The four-layer multiple BARC structure is advantageous in that the PR pattern is not affected by a change in the thickness of the second mask layer and the reflectance has a stable value of 1% or less. However, the four-layer multiple BARC structure is weak against a pattern collapse. Also, the four-layer multiple BARC structure is difficult to form because it has four layers. Moreover, the four-layer multiple BARC structure is expensive to form because its all layers are generally stacked by chemical vapor deposition (CVD). In Table 1, “minimum reflectance” means the minimum reflectance of the multiple BARC layer. That is, the reflectance of the multiple BARC layer is changed according to the thickness of the second mask layer. Here, the second mask layer has a first minimum reflectance thickness causing the reflectance to be first minimum, and a second minimum reflectance thickness causing the reflectance to be second minimum. In Table 1, “minimum reflectance<1%” means that the reflectance is lower than 1% at all of the minimum reflectance thicknesses.

In the three-layer multiple BARC structure, the transparent SOG silicon layer is used as the second mask layer. The three-layer multiple BARC structure is advantageous in that its slight footing structure is robust against a pattern collapse. Also, the three-layer multiple BARC structure is inexpensive to form because its layers are stacked by spin coating. However, the three-layer multiple BARC structure is disadvantageous in that it is sensitive to a change in the thickness of the second mask layer and has a relatively high reflectance.

### SUMMARY OF THE INVENTION

According to an aspect of the present invention, a semiconductor structure is provided which includes an etch target layer, a multiple bottom anti-reflective coating (BARC) layer which includes a first mask layer formed on the etch target layer and a second mask layer formed on the first mask layer, where the first mask layer includes carbon and the second mask layer includes silicon, and a photoresist (PR) pattern formed on the multiple BARC layer. The multiple BARC layer has a reflectance of 2% or less and an interface angle between the PR pattern and the multiple BARC layer is 80° to 90°.

According to another aspect of the present invention, a method of forming a photoresist (PR) pattern is provided which includes preparing an etch target layer, and forming a multiple bottom anti-reflective coating (BARC) layer on the etch target layer. The multiple BARC layer has a reflectance of 2% or less and includes a first mask layer formed on the etch target layer and a second mask layer formed on the first mask layer, where the first mask layer includes carbon and the second mask layer includes silicon. The method further includes forming a PR layer on the multiple BARC layer, and patterning the PR layer by photolithographic-etching the PR layer such that a PR pattern is formed having an interface angle of 80° to 90° with respect to the multiple BARC layer.

According to another aspect of the present invention, a method of forming a semiconductor pattern is provided which includes preparing an etch target layer, and forming a multiple bottom anti-reflective coating (BARC) layer on the etch target layer. The multiple BARC layer has a reflectance of 2% or less and includes a first mask layer formed on the etch target layer and a second mask layer formed on the first mask layer, where the first mask layer includes carbon and the second mask layer includes silicon. The method further includes forming a PR layer on the multiple BARC layer, and patterning the PR layer by photolithographic-etching the PR layer such that a PR pattern is formed having an interface angle of 80°to 90° with respect to the multiple BARC layer. The method still further includes patterning the second mask layer by etching using the PR pattern as a mask, patterning the first mask layer by etching using the patterned second mask layer as a mask, and patterning the etch target layer by etching using the patterned first mask layer as a mask.

### BRIEF DESCRIPTION OF THE DRAWINGS

The above and other features and advantages of the present invention will become readily apparent from the detailed description that follows, with reference to the accompanying drawings, in which:

FIGS. 1A and 1B are sectional views of a conventional four-layer multiple BARC structure and a conventional three-layer multiple BARC structure, respectively;

FIG. 2 is a graph illustrating a light energy variation in each layer of the four-layer multiple BARC structure illustrated in FIG. 1A;

FIGS. 3A and 3B are profile pictures of PR patterns that are formed using the four-layer multiple BARC structure and the three-layer multiple BARC structure, respectively;

FIGS. 4A and 4B are graphs illustrating a reflectance of a BARC/PR interface relative to the thickness of a second mask layer so as to explain the PR pattern profiles illustrated in FIGS. 3A and 3B;

FIG. 5 is a sectional view of a multiple BARC structure according to an embodiment of the present invention;

FIGS. 6A and 6B are graphs for analyzing an S/N ratio based on data according to Taguchi DOE of Table 3;

FIGS. 7A and 7B are graphs for analyzing a mean value of an interface angle;

FIG. 8 illustrates a graph of a reflectance of a BARC/PR interface depending on the thickness of a second mask layer according to an embodiment of the present invention, and a profile picture of a corresponding PR pattern;

FIG. 9 illustrates a graph of a reflectance of a BARC/PR interface depending on the thickness of a second mask layer according to an embodiment of the present invention, and a profile picture of a corresponding PR pattern;

FIGS. 10A through 10G are graphs illustrating a change in a reflectance of a BARC/PR interface according to the thickness of a second mask layer of a multiple BARC structure, which is applicable to an embodiment of the present invention, when the refractivity and absorptance of the second mask layer are changed; and

FIGS. 11A through 11H are sectional views illustrating a method of forming a multiple BARC structure and a fine pattern of a semiconductor device according to an embodiment of the present invention.

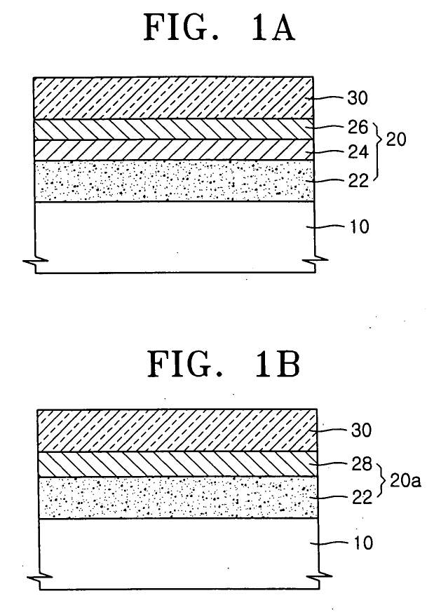

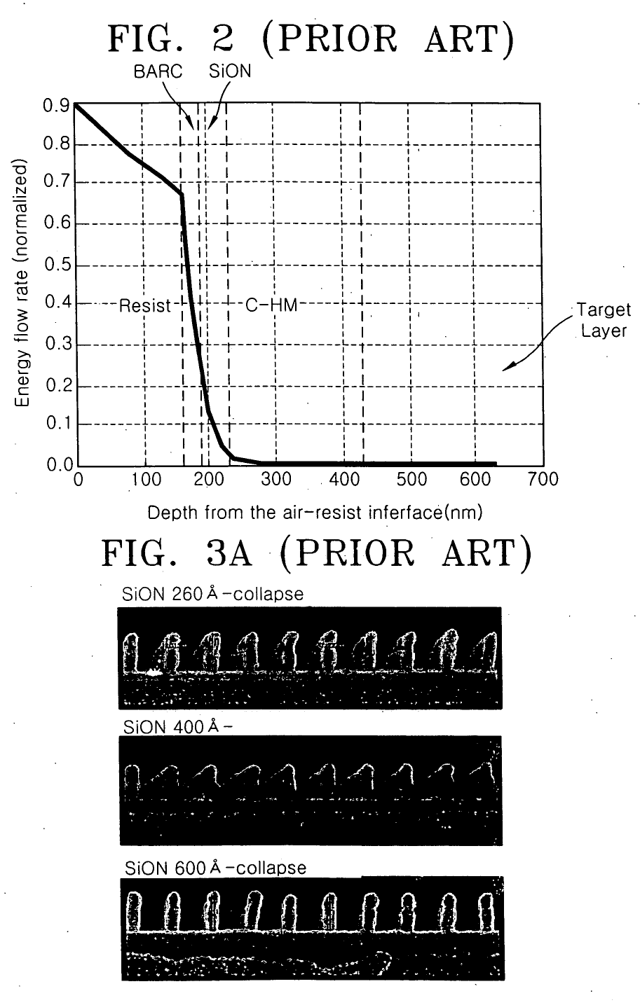

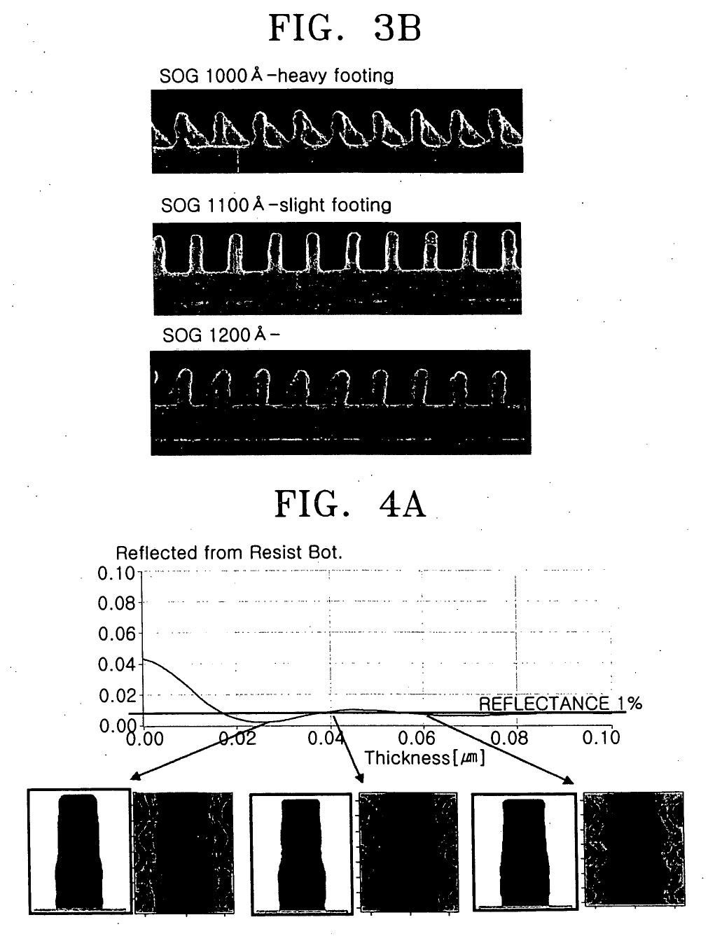

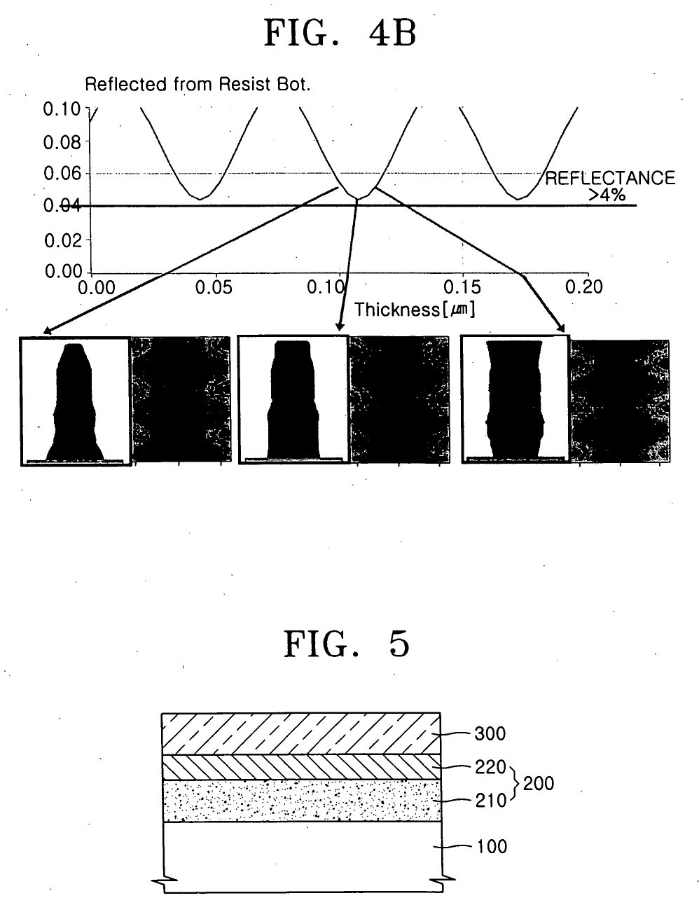

### DETAILED DESCRIPTION OF EMBODIMENTS

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the forms of elements are exaggerated for clarity. To facilitate understanding, identical reference numerals have been used, where possible, to designate identical elements that are common to the figures.

FIG. 5 is a sectional view of a multiple BARC structure according to an embodiment of the present invention.

Referring to FIG. 5, the multiple BARC structure includes an etch target layer 100, a multiple BARC layer 200, and a PR layer 300 formed on the multiple BARC layer 200. The BARC layer 200 includes a first mask layer 210 and a second mask layer 220. In contrast to the conventional three-layer multiple BARC structure, the second mask layer 220 is a silicon-containing layer whose reflectivity “n” and absorptance “k” are suitably adjusted and the first mask layer 210 contains a suitably-adjusted amount of carbon. The etch target layer 100 may be formed of SiO₂, SiN, SiON, or metal material such as copper (CU), aluminum (Al), tungsten (W), and tungsten silicide, which require the formation of a fine pattern.

The first and second mask layers 210 and 220 forming the multiple BARC layer 200 are selected using the Taguchi DOE (design of experiments) that makes it possible to optimize the material and process conditions in consideration of an reciprocating effect between a noise factor and other factors.

The corresponding Taguchi DOE is illustrated in Table 2 below.

TABLE 2

| | | | Target/Allowable | |
|---|---|---|---|---|
| | Name | Unit | Limit | Remarks |
| Charac- | PR/BARC | Degree | Nominal Best | Main |
| teristic | interface | | Charac- | Charac- |
| Values | angle | | teristics = 85° | teristic |
| | | | | Value |
| | PR/BARC | % | Smaller Better | Sub |
| | interface | | Characteristics | Charac- |
| | reflectance | | | teristic |
| | | | | Value |
| Control | n of Si-Mask | a.u. | 1.5 ≦ n ≦ 1.7 | |
| Factors | k of Si-Mask | a.u. | 0 < k < 0.2 | |
| | Bottom Hard | Type | ACL, PAE, SOC | |
| | Mask Type | | | |
| Noise | Si-Mask | A | 2nd min +/− | |
| Factor | Thickness | | 100 Å | |

Referring to Table 2, a BARC/PR interface angle is selected as a characteristic value. Here, the BARC is the second mask layer, and BARC/PR interface angle is accurately an interface angle between the BARC and a sidewall of the PR pattern that is formed by pattering the PR layer. An interface angle has a nominal best characteristic of 850, and an interface reflectance has a smaller better characteristic. The nominal best characteristic is excellent near a predetermined value, and the smaller better characteristic is excellent at a small value. The interface angle of 85° is selected as the nominal best characteristic because it is robust again a pattern collapse. The refractivity and absorptance of the second mask layer and the type of the first mask layer are selected as control factors, and allowable limits and types are set as Table 2. The allowable limit is set in consideration of the refractivity and absorptance of the conventional second mask layer. The thickness of the second mask layer is set as the noise factor in consideration of only ±100 Å of the second minimum reflectance thickness. The consideration of the thickness of the second mask layer as the noise factor aims at designing a second mask layer that is not affected by the thickness change. This is because the second mask layer may be weak again thickness changes. The reflectance is set as a sub characteristic value of the Taguchi DOE, which is not used for the direct analysis, but is considered for ascertainment of the optimal conditions.

The refractivity value of the second mask layer primarily depends on a weight percent (wt. %) of silicon, and is set to three levels from n=1.5 (the refractivity of silicon oxide containing 46-wt. % silicon) to n=1.7 (the refractivity of siloxane containing 20-wt. % silicon). The absorptance of the second mask layer depends on dye content, and is set to three levels from 0.05 to 0.15. Also, the first mask layer is classified into a deposition-type amorphous carbon layer (ACL), a polyarylene ether (PAE) layer with 60-wt. % carbon, and a spin on carbon (SOC) layer with 80-wt. % carbon.

The result of simulation according to Table 2 is illustrated in Table 3 below.

TABLE 3

| | | | | | | Interface | | | Interface | |
|---|---|---|---|---|---|---|---|---|---|---|
| Carbon | | | 2nd Min | | −100 | Angle | +100 | −100 | reflectance | +100 |
| Layer | n | K | Thickness | Dose/Focus | Å | 2nd min | Å | Å | 2nd min | Å |
| ACL | 1.5 | 0.05 | 1050 | 22.245/−0.070 | 77.60 | 84.05 | 95.55 | 2.5 | 1.3 | 2.3 |
| ACL | 1.5 | 0.1 | 1030 | 22.134/−0.077 | 90.20 | 85.96 | 89.10 | 1.1 | 0.3 | 1.0 |
| ACL | 1.5 | 0.15 | 1000 | 21.726/−0.077 | 88.93 | 90.80 | 90.01 | 1.1 | 0.5 | 1.1 |
| ACL | 1.6 | 0.05 | 980 | 22.275/−0.068 | 75.66 | 79.69 | 94.54 | 3.6 | 2.8 | 3.5 |
| ACL | 1.6 | 0.1 | 940 | 22.467/−0.080 | 81.58 | 85.45 | 87.38 | 1.7 | 1.1 | 1.6 |
| ACL | 1.6 | 0.15 | 910 | 22.078/−0.077 | 89.16 | 86.13 | 86.19 | 0.9 | 0.3 | 0.8 |
| ACL | 1.7 | 0.05 | 890 | 22.928/−0.072 | 75.66 | 73.22 | 93.89 | 4.9 | 4.7 | 4.7 |
| ACL | 1.7 | 0.1 | 820 | 22.487/−0.076 | 84.23 | 79.66 | 86.98 | 2.6 | 2.2 | 2.4 |
| ACL | 1.7 | 0.15 | 800 | 22.460/−0.078 | 92.40 | 88.66 | 89.44 | 1.3 | 0.8 | 1.2 |
| PAE | 1.5 | 0.05 | 1210 | 22.184/−0.075 | 88.15 | 89.52 | 94.62 | 1.0 | 0.2 | 0.9 |
| PAE | 1.5 | 0.1 | 1200 | 21.692/−0.084 | 94.13 | 94.50 | 91.00 | 0.5 | 0.0 | 0.4 |
| PAE | 1.5 | 0.15 | 1180 | 21.359/−0.079 | 96.63 | 85.30 | 94.13 | 0.5 | 0.1 | 0.4 |
| PAE | 1.6 | 0.05 | 1120 | 22.147/−0.083 | 87.10 | 87.36 | 90.54 | 0.8 | 0.5 | 0.8 |
| PAE | 1.6 | 0.1 | 1100 | 22.056/−0.079 | 89.41 | 89.77 | 90.36 | 0.3 | 0.1 | 0.4 |
| PAE | 1.6 | 0.15 | 1070 | 21.670/−0.081 | 88.19 | 87.38 | 91.86 | 0.2 | 0.0 | 0.2 |
| PAE | 1.7 | 0.05 | 990 | 22.294/−0.082 | 85.62 | 85.04 | 90.74 | 0.8 | 0.7 | 0.7 |
| PAE | 1.7 | 0.1 | 940 | 22.338/−0.081 | 88.32 | 93.31 | 89.11 | 0.3 | 0.1 | 0.3 |
| PAE | 1.7 | 0.15 | 930 | 21.696/−0.082 | 85.96 | 94.63 | 88.90 | 0.2 | 0.0 | 0.2 |
| SOC | 1.5 | 0.05 | 1150 | 22.092/−0.081 | 81.34 | 90.28 | 98.78 | 1.2 | 0.6 | 1.6 |
| SOC | 1.5 | 0.1 | 1100 | 21.905/−0.085 | 90.89 | 90.73 | 89.47 | 0.7 | 0.0 | 0.6 |
| SOC | 1.5 | 0.15 | 1090 | 21.665/−0.096 | 86.75 | 90.52 | 91.29 | 0.4 | 0.0 | 0.4 |
| SOC | 1.6 | 0.05 | 1050 | 22.672/−0.079 | 81.72 | 88.43 | 92.15 | 1.6 | 1.2 | 1.7 |
| SOC | 1.6 | 0.1 | 1000 | 22.159/−0.080 | 88.58 | 87.13 | 87.63 | 0.7 | 0.3 | 0.7 |
| SOC | 1.6 | 0.15 | 970 | 21.958/−0.080 | 86.28 | 91.25 | 88.78 | 0.4 | 0.0 | 0.3 |
| SOC | 1.7 | 0.05 | 920 | 22.656/−0.080 | 82.94 | 76.06 | 87.58 | 12.2 | 2.1 | 2.2 |
| SOC | 1.7 | 0.1 | 870 | 22.335/−0.078 | 88.94 | 80.36 | 87.03 | 1.0 | 0.8 | 1.0 |
| SOC | 1.7 | 0.15 | 850 | 21.969/−0.084 | 92.18 | 88.85 | 87.23 | 0.4 | 0.2 | 0.4 |

In Table 3, Dose and Focus represent the amount of incident light and a focus position, respectively. The unit of Dose is mJ/cm², and the focus position is presented in μm. The focus position has a value of 0 at a surface of the PR layer, a positive value over the surface, and a negative value under the surface. It is preferable that the incident light amount and the focus position are maintained at a constant value for the accuracy of data. It can be considered that heavy footing or undercut occur when the interface angle deviates more than 5° from 85°. The Taguchi analysis is performed using these data, where a signal to noise (S/N) ratio is considered the most important data. The S/N ratio is a value representing how stably the characteristic value is obtained with respect to the control factors, that is, process variation. It can be considered that the S/N ratio is very stable at a high value. In this experiment, a signal corresponds to the main characteristic value, and a noise corresponds to the amount of deviation from the nominal best characteristic by the noise factor (i.e., the thickness of the second mask layer). It can be said that as the main characteristic value approaches the nominal best characteristic value, the S/N ratio become larger and the effect by the noise factor, that is, the effect on the variation in the thickness of the second mask layer becomes smaller.

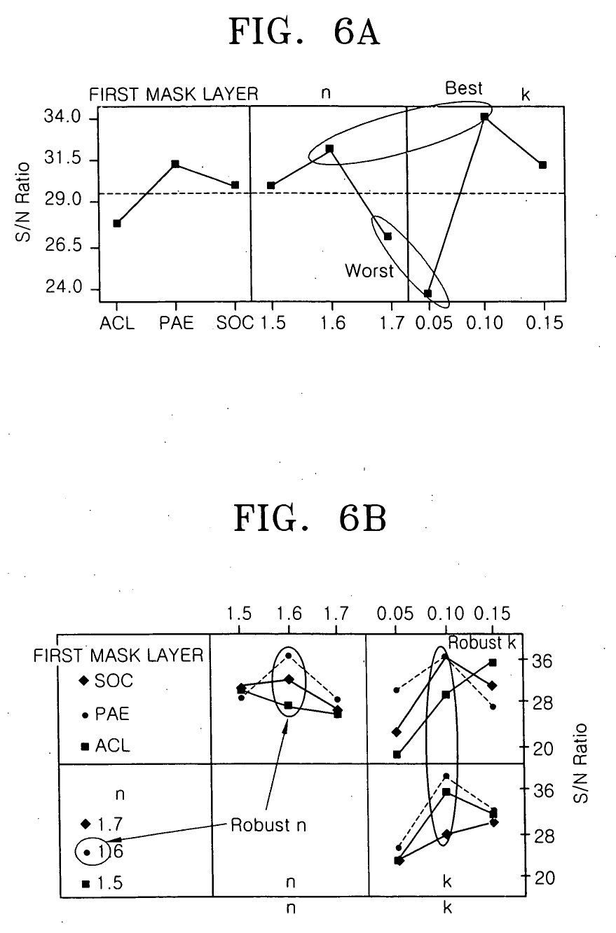

FIG. 6A is a graph illustrating the main effect on the S/N ratio by the control factors.

Referring to FIG. 6A, the second mask layer exhibits process stability with the largest S/N ratio when n=1.6 and k=0.1 (see portions denoted by “Best” in the graph). The value of k affects the process stability most greatly among the three factors. That is, the S/N ratio is changed significantly with a change of the value of k. The value of k=0.1 corresponds to a value in between the transparent SOG layer of k=0 and the BARC layer of k>0.3. The second mask layer with these values (n=1.6 and k=0.1) has a small interference effect that does not break the process stability, and thus can be considered as satisfying the characteristics of the robustness against the pattern collapse and thickness change. On the contrary, the first mask layer has the smallest effect on the S/N ratio and thus can be utilized as an adjustment factor.

FIG. 6B is a graph illustrating the reciprocating effects on the S/N ratio relative to the combination of the control factors.

Referring to FIG. 6B, when the value n and the value k are respectively 1.6 and 0.1, the S/N ratio is highest even in consideration of the reciprocating reaction on the other conditions and thus process stability is obtained. On the contrary, except for a case of k=0.05, the first mask layer factor exhibits a relatively-high S/N ratio and thus can be considered as having a small effect on the S/N ratio. A variance analysis on the S/N ratio is illustrated in Table 4 below.

TABLE 4

| Source | DF | Seq SS | Adj SS | Adj MS | F | P |
|---|---|---|---|---|---|---|
| First | 2 | 56.083 | 56.083 | 28.083 | 3.13 | 0.099 |
| Mask | | | | | | |
| Layer | | | | | | |
| n | 2 | 120.131 | 120.131 | 60.065 | 6.70 | 0.019 |
| k | 2 | 515.668 | 515.668 | 257.834 | 28.78 | 0.000 |
| First | 4 | 100.359 | 100.359 | 25.090 | 2.80 | 0.100 |
| Mask | | | | | | |
| Layer*n | | | | | | |
| First | 4 | 364.774 | 364.774 | 91.193 | 10.18 | 0.003 |
| Mask | | | | | | |
| Layer*k | | | | | | |
| n*k | 4 | 92.274 | 92.274 | 23.068 | 2.57 | 0.119 |
| Error | 8 | 71.671 | 71.671 | 8.959 | | |
| Total | 26 | 1320.960 | | | | |

Referring to Table 4, the affections of the main and reciprocating effects against the S/N ratio can be numerically reconfirmed. That is, it can be seen that the sum of squares (SS) and the mean of squares (MS) according to the value k is largest and the SS and the MS according to the first mask layer is smallest. Accordingly, it is preferable to select “n=1.6 and k=0.1” as the conditions of the second mask layer that can increase the S/N ratio and secure process stability.

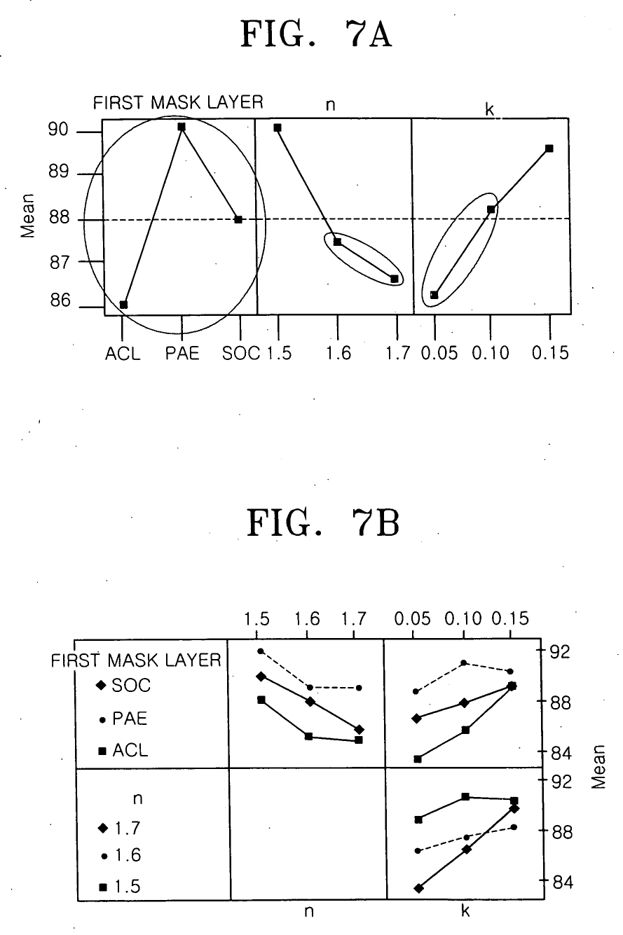

FIGS. 7A and 7B are graphs of a mean analysis for finding the condition satisfying the interface angle of 85°. Here, 85° is the interface angle considered robust against pattern collapse.

FIG. 7A is a graph illustrating the main effect on the mean value of the interface angle relative to the control factors.

As can be seen from FIG. 7A, the type of the-first mask layers most greatly affects the mean value of the interface angle. Among the first mask layers, the PAE layer has an interface angle of near 90° and thus is weakest against pattern collapse. On the contrary, the ACL layer and the SOC layer can have a relatively-stable interface angle. The second mask layer exhibits the largest S/N ratio at n=1.6 and k=0.1 in FIG. 6A or 6B, but exhibits a smaller mean value at n=1.7 and k=0.05 at the mean value of the interface angle in FIG. 7A (results are favorable as the mean value becomes near 85°). That is, it can be seen that the second mask layer is robust against pattern collapse at n=1.7 and k=0.05.

FIG. 7B is a graph illustrating the reciprocating effect on the mean value of the interface angle relative to the combination of the control factors.

As can be seen from FIG. 7B, the PAE layer among the first mask layers has a relatively-large interface angle and thus is weak against pattern collapse. On the contrary, except for n=1.5 and k=0.1 5, the ACL layer and SOC layer exhibits an interface angle that is relatively robust against pattern collapse. Meanwhile, the refractivity and absorptance exhibit the most stable interface angle at n=1.7 and k=0.05 in the main effect or FIG. 7A, but exhibit an interface angle robust against pattern collapse even at n=1.6 and k=0.1 in FIG. 7B. Accordingly, when considering the effects on the S/N ratio and the mean values, the refractivity and absorptance of the second mask layer exhibits the most stable interface angle at n=1.6 and k=0.1 and has a little effect relative to a change of thickness of the second mask layer, enabling a stable process. Also, in case of the first mask layer having little effect on the S/N ratio and substantial effect on the mean value, the ACL layer and the SOC layer (except for the PAE layer) can be used as the first mask layer of the multiple BARC.

A variance analysis on the mean value is illustrated in Table 5 below, from which the results of FIGS. 7A and 7B can be numerically reconfirmed. The type factor of the first mask layer exhibits the largest value at the SS and MS values, and most greatly contributes to the mean value of the interface angle.

TABLE 5

| Source | DF | Seq SS | Adj SS | Adj MS | F | P |
|---|---|---|---|---|---|---|
| First | 2 | 0.73425 | 0.73425 | 0.36713 | 42.07 | 0.000 |
| Mask | | | | | | |
| Layer | | | | | | |
| n | 2 | 0.57675 | 0.57675 | 0.28838 | 33.04 | 0.000 |
| k | 2 | 0.51063 | 0.51063 | 0.25531 | 29.26 | 0.000 |
| First | 4 | 0.05042 | 0.05042 | 0.01260 | 1.44 | 0.304 |
| Mask | | | | | | |
| Layer*n | | | | | | |
| First | 4 | 0.19293 | 0.19293 | 0.04823 | 5.53 | 0.020 |
| Mask | | | | | | |
| Layer*k | | | | | | |
| n*k | 4 | 0.23114 | 0.23114 | 0.05778 | 6.62 | 0.012 |
| Error | 8 | 0.06981 | 0.06981 | 0.00873 | | |
| Total | 26 | 2.36593 | | | | |

As can be seem from the above-described analysis on the S/N ratio and the mean value, the condition enabling the profile that is robust against pattern collapse and change of the thickness of the second mask layer is the forming of the second mask layer with the characteristics of n=1.6 and k=0.1. That is, the second mask layer, which is opaque and has a small reflectance, is little affected by the interference and serves as the anti-reflective layer together with the first mask layer, thereby making it possible to obtain a PR pattern profile that is robust against pattern collapse.

### Embodiment 1

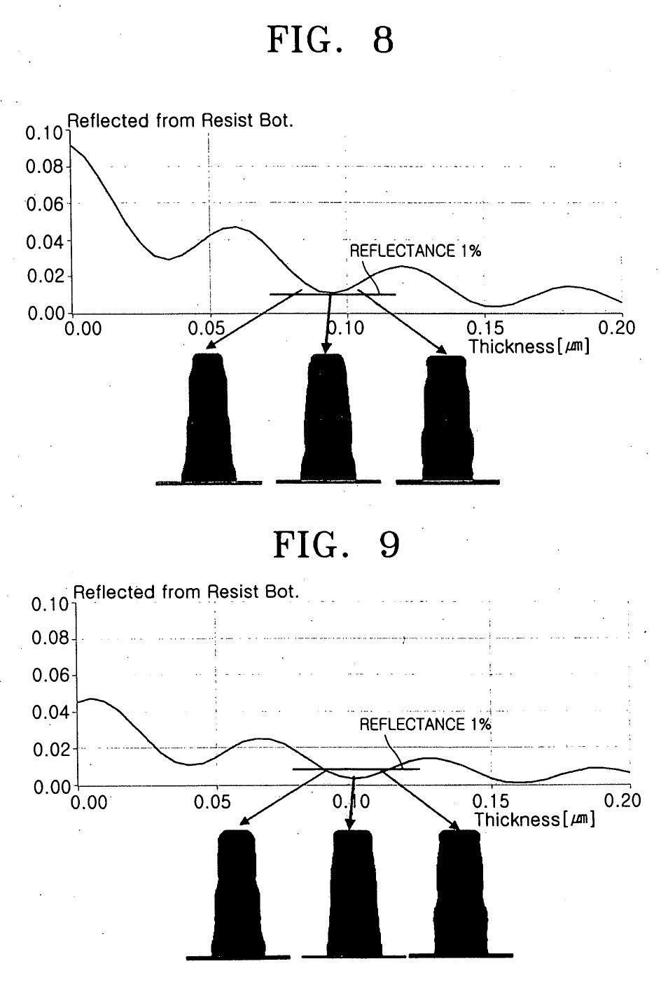

FIG. 8 illustrates a graph of the reflectance of the BARC/PR interface depending on the thickness of the second mask layer according to a first embodiment of the present invention, and a profile picture of a corresponding PR pattern near the second minimum reflectance thickness.

In the first embodiment, the second mask layer has the characteristics of n=1.6 and k=0.1, and the first mask layer is the ACL having the characteristics of n=1.0272 and k=0.5182. As can be seen from FIG. 8, the reflectance of the BARC/PR interface is stable with about 1% near the thickness 0.1 μm of the second mask layer, that is, the second minimum reflectance thickness, and the profile of the PR pattern is little affected by thickness change and has a slight footing structure that is relatively robust against pattern collapse. At this point, the second mask layer has a silicon weight percent of 30% or more, and a carbon weight percent of 80% or more. Meanwhile, the first mask layer (ACL) may have a thickness of about 0.1 to 1 μm.

### Embodiment 2

FIG. 9 illustrates a graph of the reflectance of the BARC/PR interface depending on the thickness of the second mask layer according to a second embodiment of the present invention, and a profile picture of a corresponding PR pattern at the second minimum reflectance thickness.

In the second embodiment, the second mask layer has the characteristics of n=1.6 and k=0.1. However, the first mask layer is the SOC layer having the characteristics of n=1.46 and k=0.6. The thickness and carbon weight percent of the first mask layer are the same as those of the first embodiment. FIG. 9 shows that the profile of the PR pattern is little affected by thickness change and has the slight footing structure that is robust against pattern collapse, and that the second minimum reflectance of the second mask layer occurs at a thickness of about 0.1 μm and a periphery reflectance is 1% or less.

### Embodiment 3

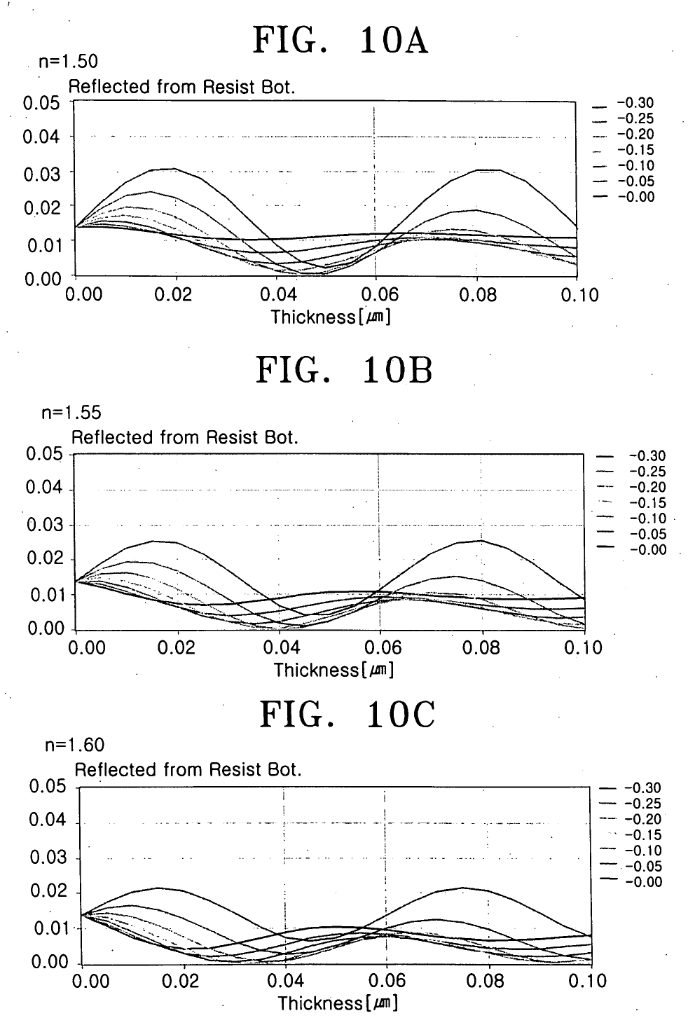

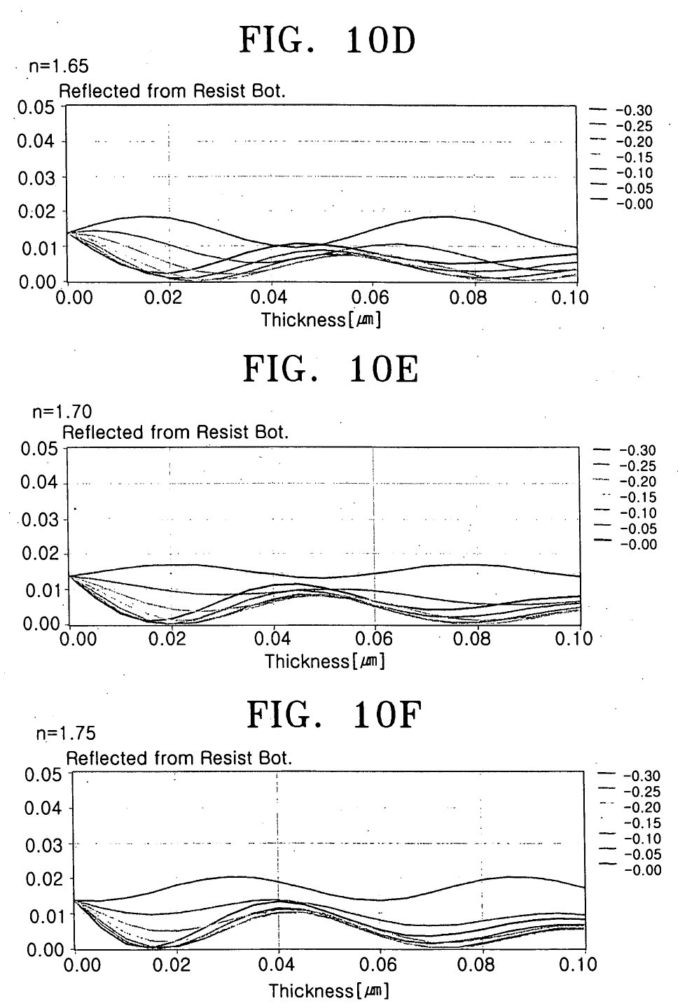

FIGS. 10A through 10G are graphs illustrating a reflectance of a BARC/PR interface versus the thickness of a second mask layer of a multiple BARC structure, which is applicable to a third embodiment of the present invention, when the refractivity and absorptance of the second mask layer change.

In the third embodiment, the first mask layer is an SOC layer of n=1.5 and k=0.29, and may have a thickness of 0.1 to 1 μm. Each graph illustrates values corresponding to a case where the refractivity of the second mask layer increases from 1.5 to 1.75 by 0.1. Each graph also represents the reflectances corresponding to the absorptances that increase from 0.00 to 0.30 by 0.05. FIGS. 10A and 10B illustrate a case where portions may have the reflectance exceeding 2% and the reflectance is significantly changed according to a change of thickness of the silicon layer. This case is considered unpreferable for the present embodiment. FIGS. 10C through 10F illustrates a case where the refractivity is relatively stable with respect to a thickness change with absorptance from 0.1 to 0.24 and has a relatively-low value of 2% or less. This case is applicable to the present embodiment. FIG. 10G illustrates a case where the reflectance is significantly changed with respect to the thickness and has a value of 2% or more, which is considered unpreferable for the present embodiment.

Consequently, the multiple BARC structure according to the third embodiment may be formed using a first SOC mask layer of n=1.5 and k=0.29 and a second mask layer with the refractivity of 1.6 to 1.75 and an absorptance of 0.1 to 0.25. This multiple BARC structure can stably control the reflectance to be less than or equal to 2%, as illustrated above.

### Embodiment 4

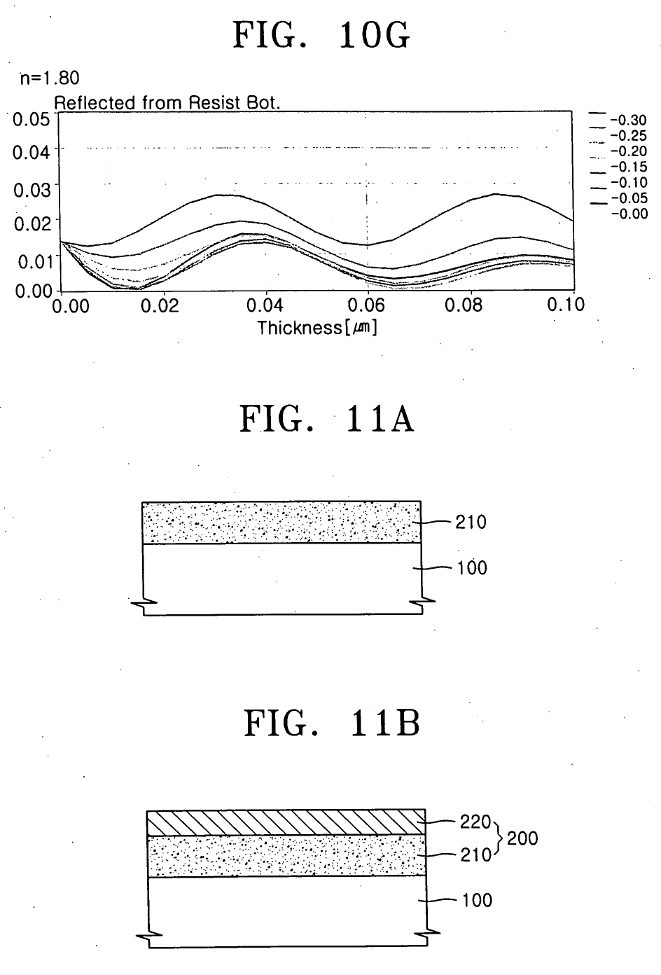

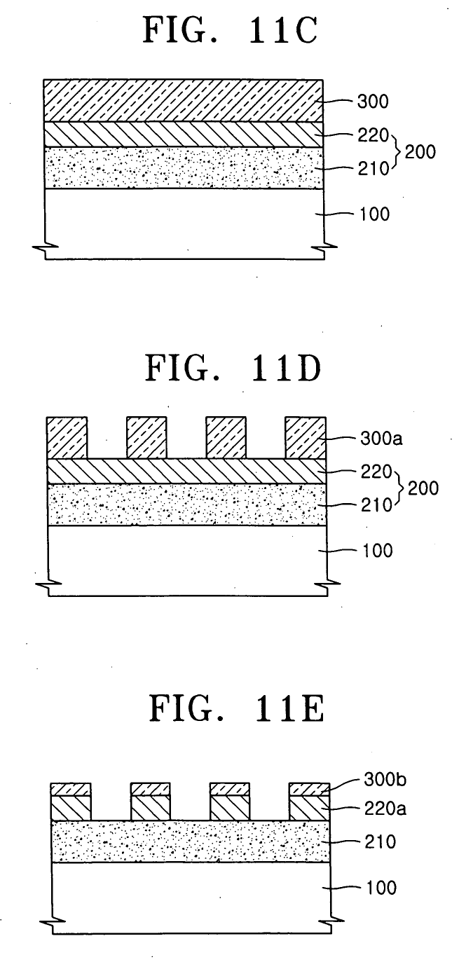

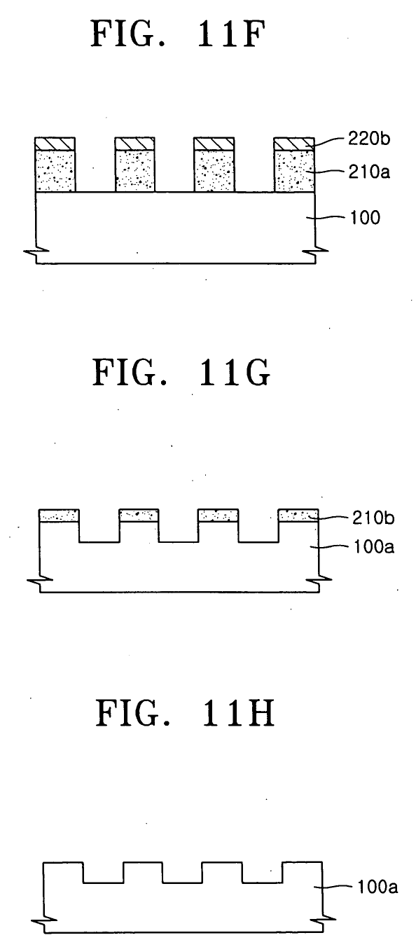

FIGS. 11A through 11H are sectional views illustrating a method of forming the multiple BARC structure (or the semiconductor structure) and a fine pattern of a semiconductor device according to a fourth embodiment of the present invention.

Referring to FIG. 11A, a first mask layer 210 is formed on an etch target layer 100 on which a fine pattern is to be formed. Here, the first mask layer may be an ACL or an SOC layer, and may be formed to a thickness of about 0.1 to 1 μm.

Referring to FIG. 11b, a second mask layer 220 is formed on the first mask layer 210, thereby forming a multiple BARC 200. Here, the second mask layer 220 has a refractivity of 1.6 to 1.75 and an absorptance of 0.1 to 0.25. The second mask layer 220 has a silicon weight percent of about 30 to 40% and a thickness of 0.03 to 0.1 μm. Preferably, the silicon weight percent and the thickness of the silicon layer are adjusted to form the second mask layer 220 with a refractivity of 1.6 and an absorptance of 0.1.

Referring to FIG. 11C, a PR layer 300 is formed on the second mask layer 220. It is preferable that the first and second mask layers 210 and 220 and the PR layer 300 are formed by spin coating.

Referring to FIG. 11D, the PR layer 300 is patterned by photolithography, and the patterned PR layer 300a is used as a mask. At this point, the PR pattern is formed with slight footing structure with the interface angle of 80 to 90°.

Referring to FIG. 11E, the second mask layer 220 is etched using the patterned PR layer 300a as a mask, resulting in an etched PR layer 300b and a patterned second mask layer 220a below the etched PR layer 300b.

Referring to FIG. 11F, the first mask layer 210 is etched using the patterned PR layer 300b and the patterned second mask layer 220a as a mask, resulting in an etched second mask layer 220b and a patterned first mask layer 210a.

Referring to FIG. 11G. the etch target layer 100 is etched using the patterned first and second mask layers 210a and 220b as a mask, resulting in an etched first mask layer 210b and the patterned etch target layer 100a.

Referring to FIG. 11H, the first mask layer is removed and thus only the patterned etch target layer 100a remains. Subsequent processes are performed in the same manner as conventional processes, and thus a description thereof will be omitted for simplicity.

Here, a 193-nm ArF Excimer laser is used as a light source for the photolithography, and the etch target layer is formed of material requiring a fine pattern of 60 nm or less.

As described above, the refractivity and absorptance of the second mask layer is suitably adjusted and the first mask layer is suitably selected. Accordingly, it is possible to form a multiple BARC layer with a low reflectance and to form the PR pattern which is robust against thickness change and pattern collapse using the multiple BARC layer. Consequently, it is possible to form a 60-nm or less fine pattern of the semiconductor device.

Also, the multiple BARC layer and the PR layer may be formed using a spin coating technique instead of the conventional CVD technique, resulting in a reduction in production cost.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor structure comprising:
an etch target layer;
a multiple bottom anti-reflective coating (BARC) layer which includes a first mask layer formed on the etch target layer and a second mask layer formed on the first mask layer, wherein the first mask layer includes carbon and the second mask layer includes silicon; and
a photoresist (PR) pattern formed on the multiple BARC layer,
wherein the multiple BARC layer has a reflectance of 2% or less and an interface angle between the PR pattern and the multiple BARC layer is 800 to 90°.

2. The semiconductor structure of claim 1, wherein the interface angle is 850.

3. The semiconductor structure of claim 1, wherein the reflectance of the multiple BARC layer depends on a thickness of the second mask layer.

4. The semiconductor structure of claim 1, wherein the second mask layer has the thickness of 0.03 μm to 0.1 μm.

5. The semiconductor structure of claim 4, wherein the second mask layer has the thickness of 0.1 μm.

6. The semiconductor structure of claim 1, wherein the multiple BARC layer has the reflectance of 1% or less.

7. The semiconductor structure of claim 1, wherein the PR pattern is formed by photolithography at a light wavelength of less than or equal to 193 nm.

8. The semiconductor structure of claim 1, wherein refractivity of the second mask layer depends on a weight percentage of silicon of the second mask layer, and an absorptance of the second mask layer depends on a dye content of the second mask layer.

9. The semiconductor structure of claim 8, wherein the weight percentage of the silicon of the second mask layer is 30% to 40%.

10. The semiconductor structure of claim 8, wherein the PR pattern is formed by photolithography using an argon fluoride Eximer laser, and wherein the second mask layer has a refractivity of 1.6 to 1.75 and an absorptance of 0.1 to 0.25.

11. The semiconductor structure of claim 10, wherein the second mask layer has a refractivity of 1.6 and an absorptance of 0.1.

12. The semiconductor structure of claim 10, wherein the first mask layer has a thickness of 0.1 μm to 1 μm.

13. The semiconductor structure of claim 10, wherein the first mask layer has a refractivity of 1.0 to 2.0 and an absorptance of 0.3 to 1.0.

14. The semiconductor structure of claim 13, wherein the first mask layer is an amorphous carbon layer having a refractivity of 1.0272 and an absorptance of 0.5182, or a spin on carbon layer having a refractivity of 1.46 and an absorptance of 0.67.

15. The semiconductor structure of claim 14, wherein the reflectance of the multiple BARC layer is less than 1%.

16. The semiconductor structure of claim 10, wherein the first mask layer is an spin on carbon layer having a refractivity of 1.5 and an absorptance of 0.29.

17. The semiconductor structure of claim 10, wherein a weight percent of carbon of the first mask layer is more than 80%.

18. The semiconductor structure of claim 1, wherein the multiple BARC layer and the PR layer are formed by spin coating.

19. The semiconductor structure of claim 1, wherein the multiple BARC layer is a dual BARC layer including the first mask layer and the second mask layer.

20. The semiconductor structure of claim 1, wherein the etch target layer is formed of a material selected from the group consisting of silicon oxide, silicon nitride, copper, aluminum, tungsten, and tungsten silicide.

21. A method of forming a photoresist (PR) pattern, the method comprising:
preparing an etch target layer;
forming a multiple bottom anti-reflective coating (BARC) layer on the etch target layer, wherein the multiple BARC layer has a reflectance of 2% or less and includes a first mask layer formed on the etch target layer and a second mask layer formed on the first mask layer, wherein the first mask layer includes carbon and the second mask layer includes silicon;
forming a PR layer on the multiple BARC layer; and
patterning the PR layer by photolithographic-etching the PR layer such that a PR pattern is formed having an interface angle of 80° to 90° with respect to the multiple BARC layer.

22. The method of claim 21, wherein the interface angle is 85°.

23. The method of claim 21, wherein the first mask layer is formed to a thickness of 0.1 μm to 1 μm, and the second mask layer is formed to a thickness of 0.03 μm to 0.1 μm.

24. The method of claim 21, wherein a refractivity of the second mask layer is adjusted by a weight percentage of silicon of the second mask layer, and an absorptance of the second mask layer is adjusted by a dye content of the second mask layer.

25. The method of claim 24, wherein the weight percentage of the silicon of the second mask layer is 30% to 40%.

26. The method of claim 24, wherein a wavelength of light used to pattern the PR layer is 193 nm, and the second mask layer has a refractivity of 1.6 to 1.75 and an absorptance of 0.1 to 0.25.

27. The method of claim 26, wherein the second mask layer has a refractivity of 1.6 and an absorptance of 0.1, and the multiple BARC layer has a reflectance of 1% or less.

28. The method of claim 26, wherein the first mask layer has a refractivity of 1.0 to 2.0 and an absorptance of 0.3 to 1.0.

29. The method of claim 28, wherein the first mask layer is an amorphous carbon layer having a refractivity of 1.0272 and an absorptance of 0.5182, or an spin on carbon layer having a refractivity of 1.46 and an absorptance of 0.67.

30. The method of claim 26, wherein the first mask layer is a spin on carbon layer having a refractivity of 1.5 and an absorptance of 0.29.

31. The method of claim 26, wherein a weight percentage of carbon of the first mask layer is more than 80%.

32. The method of claim 21, wherein the multiple BARC layer and the PR layer are stacked by spin coating.

33. The method of claim 21, wherein the multiple BARC layer is a dual BARC layer including the first mask layer and the second mask layer.

34. A method of forming a semiconductor pattern, the method comprising:
preparing an etch target layer;
forming a multiple bottom anti-reflective coating (BARC) layer on the etch target layer, wherein the multiple BARC layer has a reflectance of 2% or less and includes a first mask layer formed on the etch target layer and a second mask layer formed on the first mask layer, wherein the first mask layer includes carbon and the second mask layer includes silicon;
forming a PR layer on the multiple BARC layer; and
patterning the PR layer by photolithographic-etching the PR layer such that a PR pattern is formed having an interface angle of 800 to 90° with respect to the multiple BARC layer;
patterning the second mask layer by etching using the PR pattern as a mask;
patterning the first mask layer by etching using the patterned second mask layer as a mask;
patterning the etch target layer by etching using the patterned first mask layer as a mask.

35. The method of claim 34, wherein the interface angle is 85°.

36. The method of claim 34, wherein the first mask layer is formed to a thickness of 0.1 μm to 1 μm, and the second mask layer is formed to a thickness of 0.03 μm to 0.1 μm.

37. The method of claim 34, wherein a refractivity of the second mask layer is adjusted by a weight percent of silicon of the second mask layer, and an absorptance of the second mask layer is adjusted by a dye content of the second mask layer.

38. The method of claim 37, wherein the weight percentage of the silicon of the second mask layer is 30% to 40%.

39. The method of claim 37, wherein a wavelength of light used to form the PR pattern is 193 nm due, and the second mask layer has a refractivity of 1.6 to 1.75 and an absorptance of 0.1 to 0.25.

40. The method of claim 39, wherein the second mask layer has a refractivity of 1.6 and an absorptance of 0.1, and the multiple BARC layer has a reflectance of 1% or less.

41. The method of claim 39, wherein the first mask layer has a refractivity of 1.0 to 2.0 and an absorptance of 0.3 to 1:0.

42. The method of claim 41, wherein the first mask layer is an amorphous carbon layer having a refractivity of 1.0272 and an absorptance of 0.5182, or an spin on carbon layer having a refractivity of 1.46 and an absorptance of 0.67.

43. The method of claim 39, wherein the first mask layer is an spin on carbon layer having a refractivity of 1.5 and an absorptance of 0.29.

44. The method of claim 39, wherein a weight percentage of carbon of the first mask layer is more than 80%.

45. The method of claim 34, wherein the multiple BARC layer and the PR layer are stacked by spin coating.

46. The method of claim 34, wherein the multiple BARC layer is a dual BARC layer including the first mask layer and the second mask layer.
